(19) United States
(12) Patent Application Publication
(10) Pub. No.: US 2016/0344397 A1
(43) Pub. Date: Nov. 24, 2016

(54) LOCK DETECTION CIRCUIT, OSCILLATION SOURCE CIRCUIT AND WIRELESS DEVICE

(71) Applicant: FUJITSU LIMITED, Kawasaki-shi (JP)

(72) Inventor: Hiroshi Matsumura, Isehara (JP)

(73) Assignee: FUJITSU LIMITED, Kawasaki (JP)

(21) Appl. No.: 15/142,161

(22) Filed: Apr. 29, 2016

(30) Foreign Application Priority Data
May 18, 2015 (JP) 2015-100837

(51) Int. Cl. H03L 7/095; G01S 13/93; G01S 13/58; H03L 7/091; H03L 7/18

(52) U.S. Cl. CPC H03L 7/095; H03L 7/091; H03L 7/18; G01S 13/584; G01S 13/931

(57) ABSTRACT

A lock detection circuit includes: a phase difference detection circuit that detects a phase difference between a divided signal of an oscillation signal and a reference signal; a differentiation circuit that calculates a second differential value and a third differential value of the phase difference; and a synchronization detect circuit that detects the reference signal synchronizes with the oscillation signal, based on the secondary differential value and the third differential value.

### CROSS-REFERENCE TO RELATED APPLICATION

This application is based upon and claims the benefit of priority of the prior Japanese Patent Application No. 2015-100837, filed on May 18, 2015, the entire contents of which are incorporated herein by reference.

### FIELD

The embodiment discussed herein is related to a lock detection circuit, an oscillation source circuit, and a wireless device.

### BACKGROUND

A wireless device uses a radio-frequency signal (a local signal), as a radio signal. The local signal is generated by an unstable radio-frequency oscillator, such as a VCO and the like, is compared to a highly stable reference signal, and is feedback-controlled, so that the frequency thereof is stabilized. As such feedback control mechanisms, a PLL, an FLL, and the like are known.

A reference signal source that generates the reference signal is realized by a crystal oscillator or the like, and a crystal oscillator having a frequency of about 50 MHz is used. In contrast, the local signal, that is, for example, a millimeter-wave signal, which is used as a radio signal, is in general a signal having a frequency of several tens GHz, and therefore, a phase difference between a divided signal obtained by dividing the frequency of the local signal and the reference signal is detected and is fed back.

A vehicle millimeter-wave radar transmits a FMCW-modulated radio signal, receives a reflected signal, and extracts a Doppler component in an intermediate frequency signal to detect a distance from a target object and a relative speed. Therefore, a local signal the frequency of which repeatedly changes in a linear manner between an upper limit and a lower limit is generated.

Using a feedback control mechanism, such as a PLL and the like, a state in which a local signal that is generated has a predetermined relationship with a reference signal is maintained. Even when a voltage change and a temperature change in a certain extent occur, such a synchronous state is normally feedback-controlled, and a stable state is maintained. However, when a large impact, such as a large power supply voltage fluctuation, a temperature change, an erroneous operation in a digital circuit, and the like, is applied from the outside of a loop, synchronization is deviated,and the local signal is made unstable and is put in an asynchronous state in which the local signal does not have the predetermined relationship with the reference signal. When the local signal is put in such a state, the function as wireless device itself is lost.

Therefore, it is desired that, in a wireless device, an asynchronous state of a local signal with a reference signal is detected accurately at high speed, and a lock detection circuit is used. A lock detection circuit in accordance with the related art is configured to integrate a frequency difference as a phase over long time and detects a frequency difference, based on change in the integrated phase (logic change). Therefore, there has been a problem in which, in an unlock state in which a frequency difference is small; it takes a very long time to detect the frequency difference. In other words, there has been a problem in which it is not detected for a long time that the local signal is put in an asynchronous state.

This problem is important, specifically, in a wireless device, such as a vehicle millimeter-wave radar and the like, which is related to safety, and there is a probability that, if an operation in an asynchronous state is continued, an erroneous operation of the radar is caused and a danger arises due to wrong automobile control. Therefore, a time (a time lag) from the occurrence of an asynchronous state to detection thereof is desired to be as small as possible.

The followings are reference documents.
[Document 1] Japanese Laid-open Patent Publication No. 2010-237172 and
[Document 2] Japanese Laid-open Patent Publication No. 2013-002949.

### SUMMARY

According to an aspect of the invention, a lock detection circuit includes: a phase difference detection circuit that detects a phase difference between a divided signal of an oscillation signal and a reference signal; a differentiation circuit that calculates a second differential value and a third differential value of the phase difference; and a synchronization detect circuit that detects the reference signal synchronizes with the oscillation signal, based on the secondary differential value and the third differential value.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a basic configuration of a wireless device;

FIG. 2 is a diagram illustrating a configuration of a local signal generation circuit (a millimeter-wave signal generator) together with a reference signal source;

FIG. 3A is a chart illustrating a synchronous state of an operation of a lock detection circuit;

FIG. 3B is a chart illustrating an asynchronous state of the operation of a lock detection circuit;

FIG. 4A is a chart illustrating an example of a physical variable of detection principles when an asynchronous state according to an embodiment;

FIG. 4B is a chart illustrating a phase difference between a reference signal and a divided signal when an asynchronous state according to an embodiment;

FIG. 4C is a chart illustrating a phase difference signal when an asynchronous state according to an embodiment;

FIG. 4D is a chart illustrating a primary differentiation when an asynchronous state according to an embodiment;

FIG. 4E is a chart illustrating a secondary differentiation when an asynchronous state according to an embodiment;

FIG. 5 is a diagram illustrating a configuration of a local signal generation circuit (a millimeter-wave signal generator) according to the embodiment together with a reference signal source;

FIG. 6 is a diagram illustrating a configuration of a lock detection circuit of the local signal generation circuit according to the embodiment;

FIG. 7 is a diagram illustrating a circuit configuration of a phase difference detection circuit;

FIG. 8 is a time chart illustrating an operation of the phase difference detection circuit;

FIG. 9 is a chart illustrating digital processing performed in a phase calculation circuit;

FIG. 10 is a circuit diagram of a differentiation circuit; and

FIG. 11 is a flow chart illustrating processing performed in synchronization detect circuit.

### DESCRIPTION OF EMBODIMENT

Before describing a lock detection circuit according to an embodiment, a general lock detection circuit, and an oscillation source circuit and a wireless device which employ the general lock detection circuit will be described.

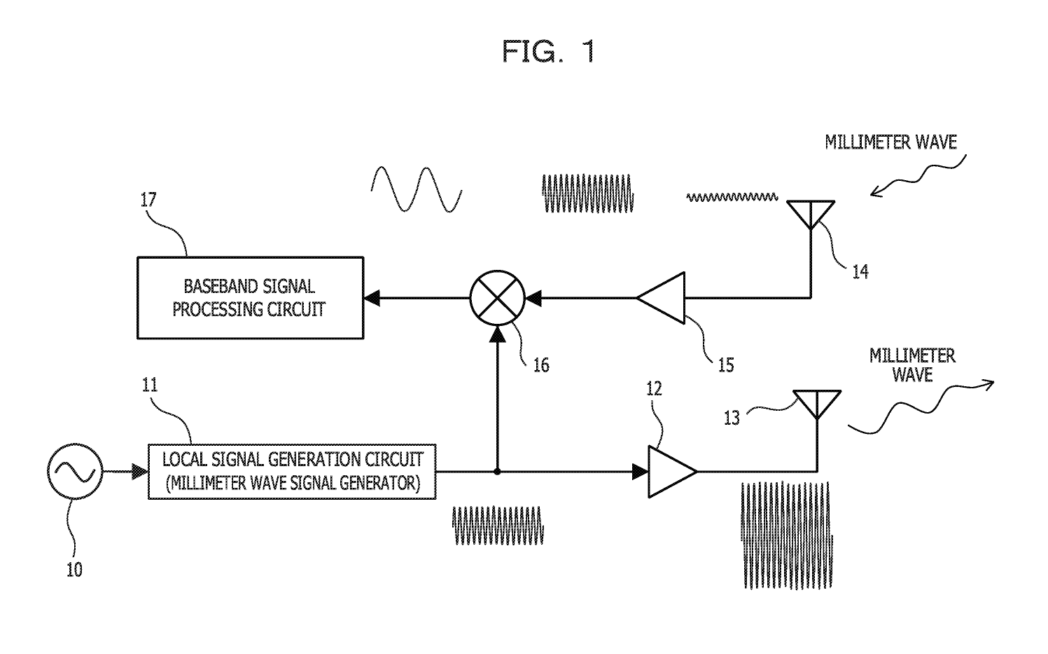

FIG. 1 is a diagram illustrating a basic configuration of a wireless device.

A wireless device includes a reference signal source 10, a local signal generation circuit (millimeter-wave signal generator) 11, an amplifier 12, a transmission antenna 13, a reception antenna 14, an amplifier 15, a mixer 16, and a baseband signal processing circuit 17. The reference signal source 10 includes a crystal oscillator and the like, and outputs a reference signal having a certain frequency (for example, 50 MHz). A case in which a millimeter-wave signal is used as a radio signal will be described as an example below, and the local signal generation circuit 11 will be occasionally referred to as a “millimeter-wave signal generator”.

The local signal generation circuit 11 includes a variable frequency oscillation circuit that oscillates at several tens GHz, and a feedback control circuit that feedback-controls the variable frequency oscillation circuit such that an oscillation signal that is output by the variable frequency oscillation circuit has a predetermined relationship with a reference signal. The variable frequency oscillation circuit is formed, for example, by a voltage-controlled oscillator (VCO), a current-controlled oscillator (ICO), or the like. The feedback control circuit is realized by a PLL circuit that divides the frequency of an oscillation signal that is output by the variable frequency oscillation circuit, detects a phase difference between a divided signal and the reference signal, and applies a control signal generated by cutting a radio-frequency component of the phase difference signal to the variable frequency oscillation circuit. Also, the feedback control circuit is realized by a circuit that detects a frequency difference between the divided signal and the reference signal and feedbacks the frequency difference. In a manner described above, the local signal generation circuit 11 generates a local signal that has a predetermined relationship with a reference signal and is modulated in accordance transmission data.

The amplifier 12 amplifies the local signal. The amplified local signal is output from the transmission antenna 13. The reception antenna 14 receives a radio-frequency signal corresponding to the local signal. The radio-frequency signal is amplified by the amplifier 15. The mixer 16 mixes the radio-frequency signal amplified by the amplifier 15 and the local signal to generate an intermediate frequency (IF) signal. For example, after converting the intermediate frequency signal to a digital signal, the baseband signal processing circuit 17 digitally processes the digital intermediate frequency signal, and acquires reception data.

For example, a vehicle millimeter-wave radar transmits an FMCW modulated signal, receives a reflected signal, and extracts a Doppler component in the intermediate frequency signal to detect a distance from a target object and a relative speed. In this case, the local signal generation circuit 11 outputs a local signal the frequency of which repeatedly changes in a linear manner between an upper limit and a lower limit.

The basic configuration of the wireless device in a reception circuit, which is illustrated in FIG. 1, is widely known, and therefore, the further description thereof will be omitted. Note that a lock detection circuit according to an embodiment, which will be described below, is a circuit used in the wireless device of FIG. 1 or the like.

In the wireless device of FIG. 1, in a normal state, the local signal generation circuit 11 is put in a lock (synchronous) state, and a state in which a local signal generated by the local signal generation circuit 11 has a predetermined relationship with a reference signal is maintained. Even when a voltage change and a temperature change in a certain extent occurs, such a synchronous state is normally feedback-controlled, and a stable state is maintained. However, when a large impact, such as a large power supply voltage fluctuation, a temperature change, an erroneous operation in a digital circuit, and the like, is applied from the outside of a loop, synchronization is deviated,and the local signal is made unstable and is put in an asynchronous state in which the local signal does not have the predetermined relationship with the reference signal. When the local signal is put in such a state, the function as wireless device itself is lost.

Thus, in the wireless device, it is desired that an asynchronous state of the local signal generation circuit (millimeter-wave signal generator) 11 is detected accurately at high speed.

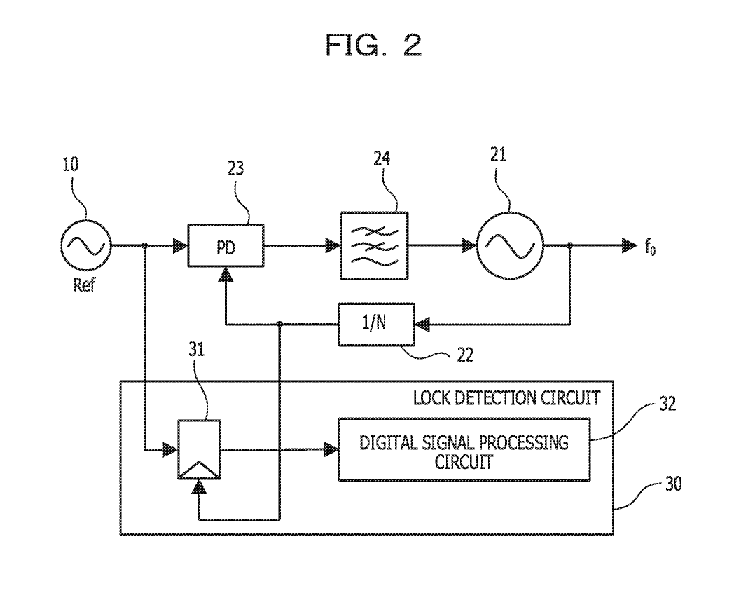

FIG. 2 is a diagram illustrating a configuration of a local signal generation circuit (a millimeter-wave signal generator) together with a reference signal source.

The local signal generation circuit 11 includes a voltage-controlled oscillator (VCO) 21, a 1/N frequency divider 22, a phase comparator (PD) 23, a lowpass filter 24, and a lock detection circuit 30. The VCO 21 is an oscillation circuit the oscillation frequency of which changes in accordance with a voltage that is applied and which generates a local signal having a frequency f₀. The 1/N frequency divider 22 divides the frequency of the local signal into 1/N, and generates a divided signal having a frequency approximate to the frequency of the reference signal. The PD 23 detects a phase difference between the reference signal and the divided signal, and generates a phase difference signal. The low pass filter 24 removes a radio-frequency component from the phase difference signal to generate a VCO control voltage signal. The VCO control voltage signal is applied to the VCO 21. With the above-described configuration, the local signal is feedback-controlled to be a signal having a predetermined relationship (for example, at an N-fold frequency in the same phase) with the reference signal. Therefore, in a locked synchronous state, the VCO 21 outputs the local signal having the predetermined relationship with the reference signal.

The lock detection circuit 30 includes a flip-flop (F/F) 31 that latches the reference signal in accordance with the divided signal, and a digital signal processing circuit 32.

The local signal generation circuit 11 illustrated in FIG. 2 is a circuit that compares an unstable oscillation signal of the millimeter-wave oscillator (VCO) 21 to a highly stable reference signal, feedback-controls the oscillation signal, and thereby stabilizes the frequency of the oscillation signal.

The configuration of the local signal generation circuit 11, which is illustrated in FIG. 2, is widely known as a PLL circuit, and therefore, the further description thereof will be omitted.

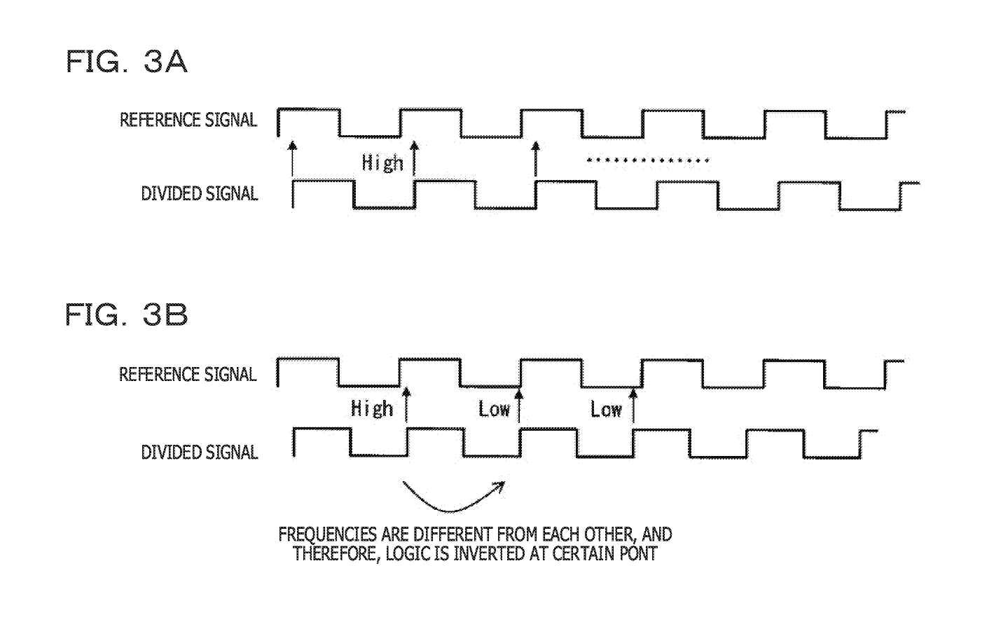

FIG. 3A and FIG. 3B are charts illustrates an operation of the lock detection circuit 30, FIG. 3A is a chart illustrating a synchronous state, and FIG. 3B is a chart illustrating an asynchronous state.

As illustrated in FIG. 3A, when, in a state in which a reference signal and a divided signal have the same frequency and the phases of the reference signal and the divided signal are shifted from one another, the reference signal is latched at a rise of the divided signal, a latched value does not change and continues to be a certain value (High in the FIG. 3A). A case in which the reference signal and the divided signal have the same frequency will be hereinafter referred to as a “synchronous state”. When the phases of the reference signal and the divided signal are between 180 degrees and 360 degrees, the latched value is Low.

As illustrated in FIG. 3B, when, in an asynchronous state in which the frequencies of the reference signal and the divided signal are different from each other, the reference signal is latched at a rise of the divided signal, a phase difference gradually changes, and the latched value is inverted at a certain point. Therefore, the digital signal processing circuit 32 monitors an output of the F/F 31, and determines, if the output does not change, that a synchronous state has occurred, and if the output changes, that an asynchronous state has occurred.

Note that, although, in FIG. 2, an example in which a reference signal is latched at a rise of the divided signal is illustrated, it is also possible to latch the divided signal at a rise of the reference signal.

As illustrated in FIG. 3B, when the frequencies of the reference signal and the divided signal are approximate to each other, depending on an initial phase difference, it takes a long time for the latched value to be inverted. That is, the lock detection circuit 30 of FIG. 2 integrates a frequency difference as a phase over long time to detect a frequency difference, based on change in the integrated phase (logic change). Therefore, there has been a problem in which, in an unlock state in which the frequency difference is small; it takes a very long time to detect the frequency difference. In other words, there has been a problem in which it is not detected for a long time that an asynchronous state has occurred.

For example, it is assumed that the 1/N frequency divider 22 divides the frequency at a division ratio N=about 1500, a desired frequency of the local signal is 77.00 GHz, an actual frequency of the local signal is 77.01 GHz, and the local signal is in an asynchronous state. The frequency difference is 77.01 GHz-77.00 GHz=10 MHz, and 10 MHz/the division ratio (about 1500) =6.7 kHz. The frequency fref=50 MHz of the reference signal is inverted once during 50 MHz/6.7 kHz=about 7500 clocks (150 μs). Therefore, it takes about 100 μs to detect an asynchronous state.

This problem is important, specifically, in a wireless device, such as a vehicle millimeter-wave radar and the like, which is related to safety, and there is a probability that, when an operation in an asynchronous state is continued, an erroneous operation of the radar is caused and a danger arises due to wrong automobile control. Therefore, a time (a time lag) from the occurrence of an asynchronous state to detection thereof is desired to be as small as possible.

The above-described lock detection method in accordance with the related art is realized by a system, that is, an integral type synchronization detection circuit, in which a frequency difference between two signals is integrated over long time and change in the integrated phase is detected. In contrast, a lock detection method according to the embodiment, which will be described below, is realized by a system, that is, a differential type synchronization detection circuit, in which a phase differences between two signals is monitored and detection is performed, based on the amount of temporal change in the phase difference.

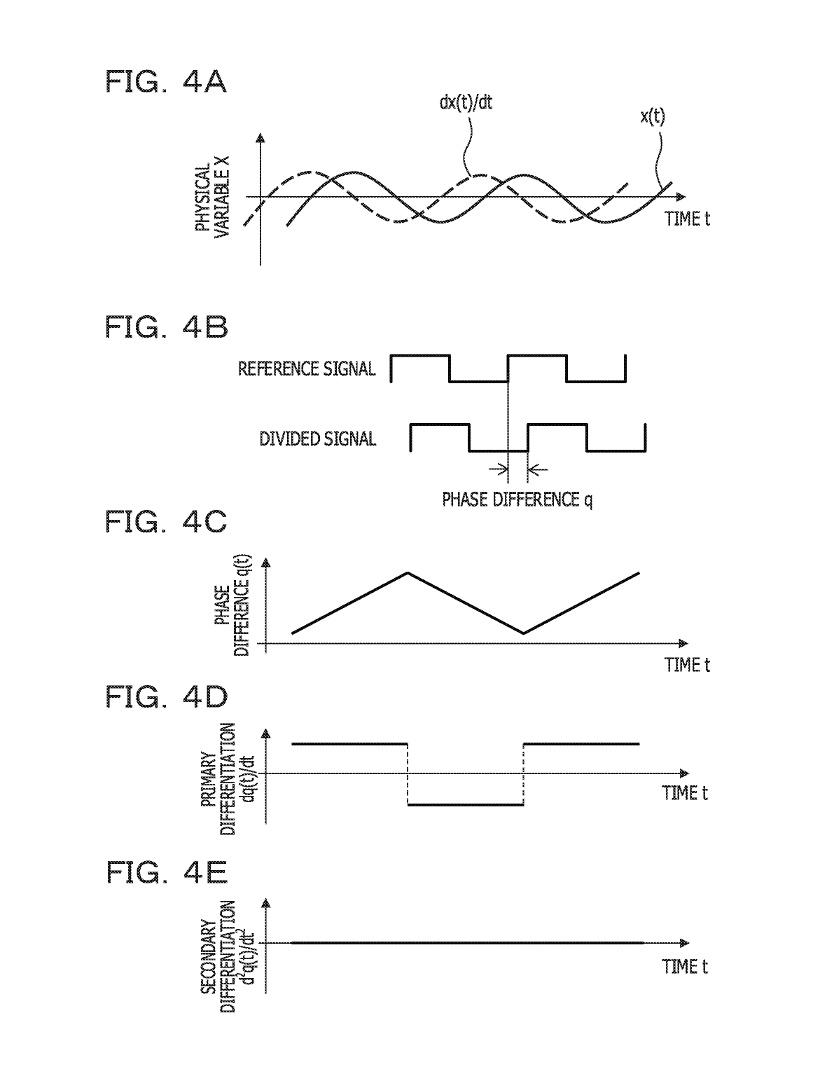

FIGS. 4A to 4E are charts illustrating detection principles of an asynchronous state according to the embodiment, FIG. 4A is a chart illustrating an example of a physical variable, FIG. 4B is a chart illustrating a phase difference between a reference signal and a divided signal, FIG. 4C is a chart illustrating a phase difference signal, FIG. 4D is a chart illustrating a primary differentiation, and FIG. 4E is a chart illustrating a secondary differentiation.

An asynchronous state is a state in which a signal indicating a state oscillates.

An oscillation state of a physical variable x(t) will be considered. In FIG. 4A, the physical variable x(t) oscillates, and a primary differentiation signal dx(t)/dt also oscillates. When the physical variable x(t) is in a stable state (a synchronous state), x(t)=0 and dx(t)/dt=0 are achieved. When the physical variable x(t) is in an unstable state (an asynchronous state), x(t)≠0 or dx(t)/dt ≠0 is achieved.

In evaluating the stability of a feedback circuit, how the physical variable x(t) indicating a stable state is selected is an issue, and in a stable state (a lock state), a variable with which x(t)=0 is achieved is selected.

In this case, as a variable, which is a source of a physical variable used for evaluating the stability in a PLL circuit used in an FMCW radar, as illustrated in FIG. 4B, a phase difference q between the reference signal and the divided signal is used. In the FMCW radar, the frequency is caused to repeatedly change in a linear manner between an upper limit and a lower limit, and therefore, as illustrated in FIG. 4C, a phase difference q(t) also repeatedly changes in a linear manner between an upper limit and a lower limit.

As illustrated in FIG. 4D, when the primary differentiation dq(t)/dt of the phase difference q(t) reaches the upper limit and the lower limit, the primary differentiation dq(t)/dt is the corresponding one of a certain positive value and a certain negative value. Furthermore, as illustrated in FIG. 4E, a secondary differentiation d²q(t)/dt² is 0 at all times. Therefore, it is assumed that the secondary differentiation d²q(t)/dt² of the phase difference q(t) is a state variable x(t). Then, an unstable state (an asynchronous state) is detected from the secondary differentiation d²q(t)/dt², and a differentiation (a tertiary differentiation) thereof.

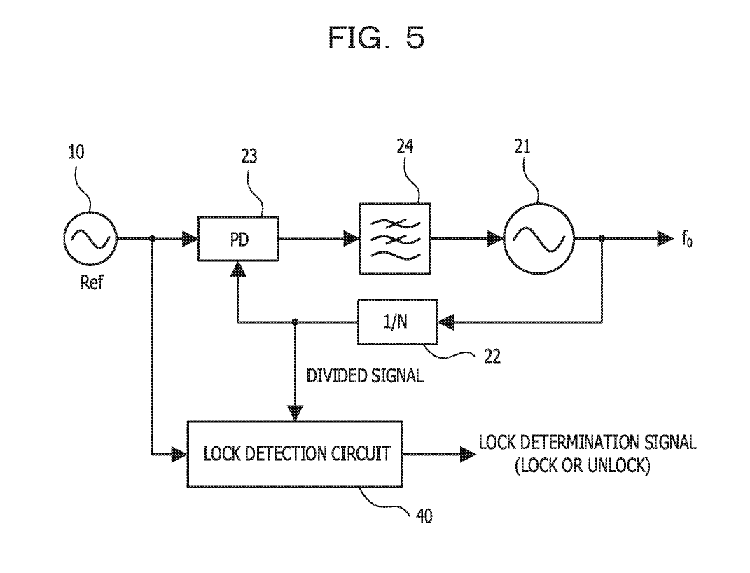

FIG. 5 is a diagram illustrating a configuration of a local signal generation circuit (a millimeter-wave signal generator) according to the embodiment together with a reference signal source.

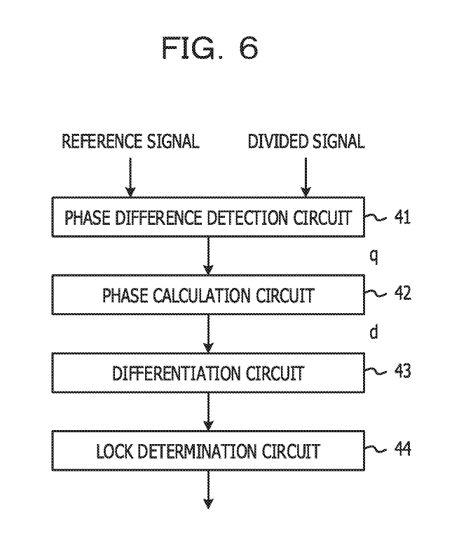

FIG. 6 is a diagram illustrating a configuration of a lock detection circuit 40 of the local signal generation circuit according to the embodiment.

The local signal generation circuit (a millimeter-wave signal generator) according to the embodiment may be used as the local signal generation circuit (the millimeter-wave signal generator) 11 of the wireless device of FIG. 1, and is, specifically, appropriate for the use in a wireless device having an FMCW radar function, but the application of the local signal generation circuit (a millimeter-wave signal generator) according to the embodiment is not limited thereto.

The local signal generation circuit (a millimeter-wave signal generator) according to the embodiment includes the voltage-controlled oscillator (VCO) 21, the 1/N frequency divider 22, the phase comparator (PD) 23, the lowpass filter 24, and a lock detection circuit 40. The VCO 21, the 1/N frequency divider 22, the PD 23, and the lowpass filter 24 are formed in a similar manner as illustrated in FIG. 2, and therefore, the description thereof in detail will be omitted. In other words, in the local signal generation circuit (a millimeter-wave signal generator) according to the embodiment, the lock detection circuit is different from a lock detection circuit in accordance with the related art.

As illustrated in FIG. 6, the lock detection circuit 40 includes a phase difference detection circuit 41, a phase calculation circuit 42, a differentiation circuit 43, and a synchronization detect circuit 44.

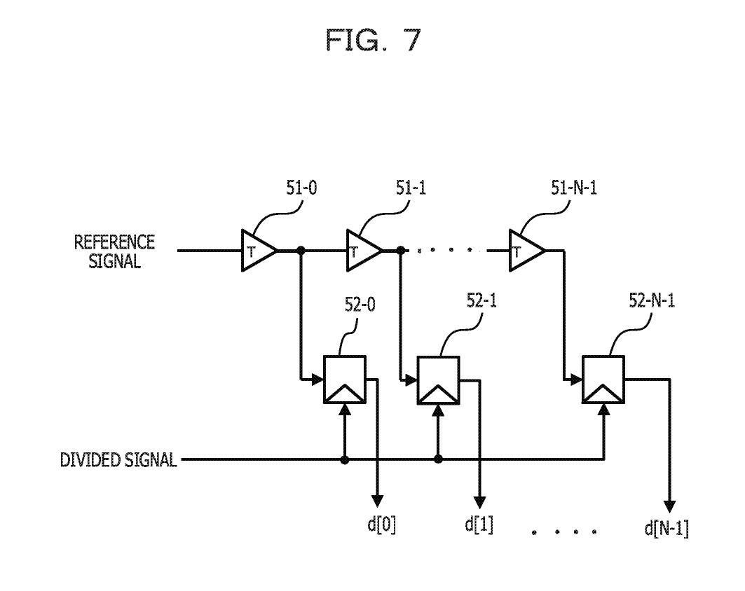

FIG. 7 is a diagram illustrating a circuit configuration of the phase difference detection circuit 41.

The phase difference detection circuit 41 of FIG. 7 is generally called time-to-digital converter (TDC) circuit. The phase difference detection circuit 41 includes delay lines 51-0, 51-1, . . . , and 51-N-1 that delay a reference signal in a plurality of stages and generate a plurality of delay signals with different delay amounts, and latch lines 52-0, 52-1, . . . , and 52-N-1 that latch a plurality of delay signals with a divided signal. The delay lines 51-0, 51-1, . . . , and 51-N-1 have the same delay amount. Outputs of the latch lines 52-0, 52-1, . . . , and 52-N-1 are 1[0], q[1], . . . , and q[N-1].

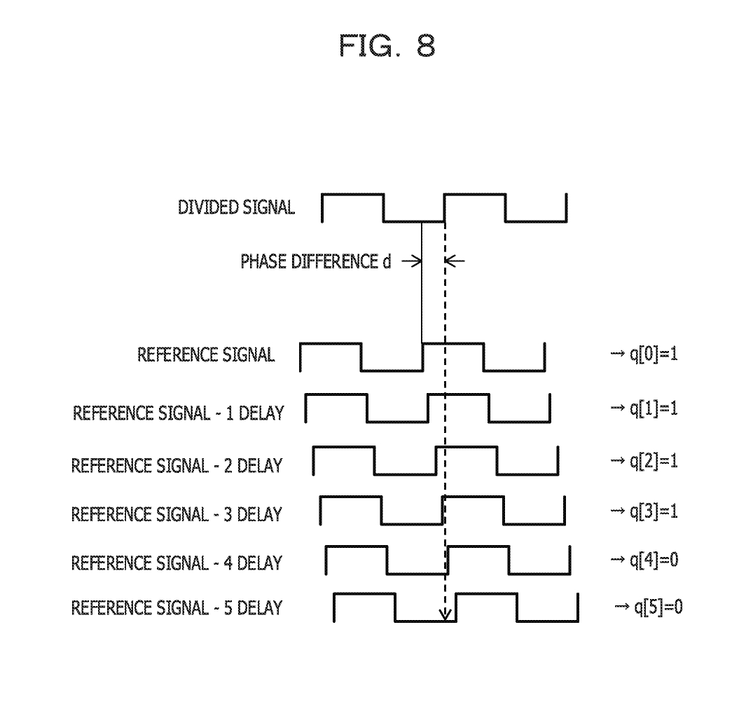

FIG. 8 is a time chart illustrating an operation of the phase difference detection circuit 41.

The reference signal is delayed in a plurality of stages by the delay lines 51-0, 51-1, . . . , and 51-N-1. Each of the outputs of the latch lines 52-0, 52-1, . . . , and 52-N-1, which has been latched at a rise of the divided signal changes halfway, and a position in which the output changes is determined by a phase difference of the divided signal relative to the reference signal. The example of FIG. 8 illustrates q[0] to q[3]=1 and q[4] to q[5]=0. Therefore, when a position in which a value of any one of the outputs of the latch lines 52-0, 52-1, . . . , and 52-N changes is detected, a value in which the phase difference of the divided signal relative to the reference signal is digital-converted is obtained. In a PLL, this phase difference is in a proportional relation with the output frequency of the VCO 21. That is, a temporal change in the digital phase difference q is proportional to a temporal change of the output frequency f₀.

Although, in FIG. 7 and FIG. 8, an example in which the reference signal is delayed and is latched with the divided signal is illustrated, a configuration in which the divided signal is delayed and is latched using the reference signal may be also employed.

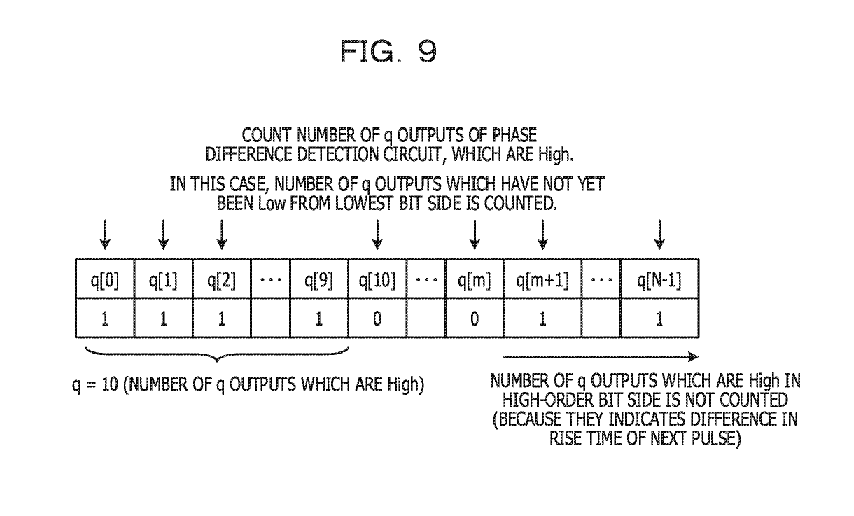

FIG. 9 is a chart illustrating digital processing performed in the phase calculation circuit 42.

The phase calculation circuit 42 receives digital signals q[0] to q[N-1] each indicating a phase difference output by the phase difference detection circuit 41, and processes the digital signals q[0] to q[N-1]. The digital signals q[0] to q[N-1] are updated in one cycle of the divided signal, and therefore, processing is completed during one clock, assuming that the divided signal is a clock.

The phase calculation circuit 42 counts the number of ones of the digital signals q[0] to q[N-1], values of which have not yet changed, from the side of q[0]. In the example of FIG. 9, the phase calculation circuit 42 counts the number of ones of the digital signals q[0] to q[N-1], values of which are 1 (High). In this case, the number of ones of the digital signals q[0] to q[N-1], values of which are 1 and have not yet become 0 (Low),is counted from the side of q[0] that is the lowest bit,and the number of ones of the digital signals q[0] to q[N-1], values of which have become 0 once and then become 1 (High) at the side of q[N-1], is not counted. This is because each of ones of the digital signals q[0] to q[N-1], values of which are 1 at the side of q[N-1], indicates a rise time of a next pulse. Also, if q[0]=0 is satisfied, the number of ones of the digital signals q[0] to q[N-1], values of which are 0 and have not yet become 1, is counted from the side of q[0]. The phase calculation circuit 42 outputs data d that indicates the counted number of ones of the digital signals q[0] to q[N-1]. The data d has a bit number that may indicate the number of ones of the digital signals q[0] to q[N-1] which corresponds to a largest phase difference.

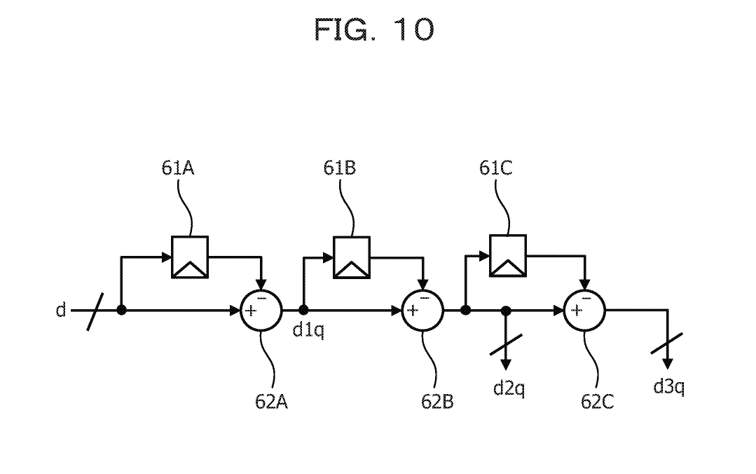

FIG. 10 is a circuit diagram of the differentiation circuit 43. The differentiation circuit 43 operates using the divided signal as a clock. The differentiation circuit 43 includes differentiation circuits of three stages.

A differentiation circuit of a first stage includes an F/F 61A that holds the data d for one clock cycle and a difference arithmetic circuit 62A that calculates a difference between the data d and an output of F/F 61A. The output of the F/F 61A is data one cycle before, and a difference between the data d and the output of the F/F 61A corresponds to a primary differential calculus of the data d. That is, the differentiation circuit 43 outputs the primary differential calculus d1q (dq/dt) of the data d.

A differentiation circuit of a second stage includes an F/F 61B that holds the primary differential calculus d1q for one clock cycle, and a difference arithmetic circuit 62B that calculates a difference between the primary differential calculus d1q and an output of the F/F 61B, and outputs a differentiation of the primary differential calculus d1q, that is, a second differential calculus d2q (d²q/dt²) of the data d.

A differentiation circuit of a third stage includes an F/F 61C that holds the secondary differentiation d2q for one clock cycle and a difference arithmetic circuit 62C that calculates a difference between the secondary differentiation d2q and an output of the F/F 61C, and outputs a differentiation of the secondary differentiation d2q, that is, a third differential calculus d3q (d³q/dt³) of the data d.

The synchronization detect circuit 44 performs lock determination using the secondary differentiation d2q and the tertiary differentiation d3q output by the differentiation circuit 43. In the FMCW radar, the frequency of the local signal linearly changes and, in a lock state, the data d that corresponds to the phase difference q linearly changes relative to time. Therefore, as for d1q, d2q, and d3q obtained by differentiating the data d, d1q=a certain value, d2q=0, and d3q=0 are achieved. That is, when d2q=0 and d3q=0 are satisfied, a lock state (a synchronous state) is determined, and when d2q≠0 and d3q≠0 are satisfied, an unlock state (an asynchronous state) is determined.

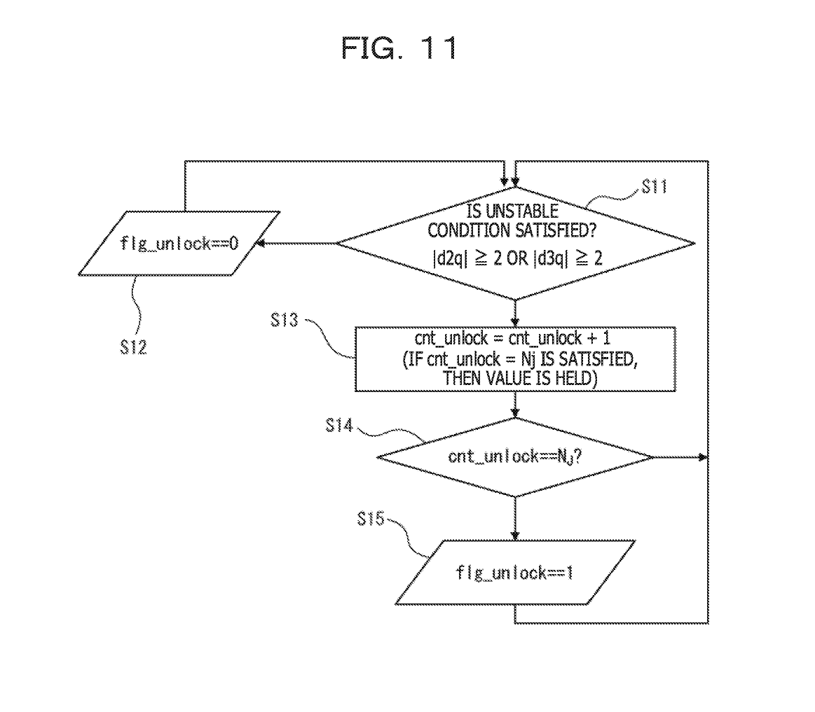

FIG. 11 is a flow chart illustrating processing performed in the synchronization detect circuit 44.

In Step S11, whether or not an unstable condition (|d2q|≧2 or |d3q|≧2) is satisfied is determined, if not satisfied, the process proceeds to Step S12, and if satisfied, the process proceeds to Step S13. In this case, a margin is provided for a determination condition, and an unstable condition is set to |d2q|≧2 or |d3q|2.

In Step S12, a flag flag_unlock, which indicates a time of an unlock state, is set to 0, and the process returns to Step S11.

In Steps S13 to S15, in order not to cause false detection, processing is performed such that, if it is detected that the unstable condition is satisfied only once, determination is not made, but if it is detected that the unstable condition is satisfied consecutively a plurality of times, an “asynchronous state” is determined.

In Step S13, a parameter cnt_unlock, which indicates the number of times the unstable condition is consecutively satisfied, is increased by one. In this case, if cnt_unlock=Nⱼ is satisfied, the then value is held.

In Step S14, whether or not the parameter cnt_unlock=Nⱼ is satisfied is determined, if a result of determination is YES, the process proceeds to Step S15, and if the result is NO, the process returns to Step S11.

In Step S15, the flag flag_unlock=1 is set, the process returns to Step S11. Therefore, while a state in which the unstable condition is satisfied continues, flag_unlock=1 is held.

It is indicated by flag_unlock=1 that the PLL is in an asynchronous state, and the function as a wireless device is lost, and therefore, when an unlock state (flag_unlock=1) is detected, an operation of a wireless part is stopped and recovery control is performed.

As has been described above, a wireless device and a lock detection circuit according to the above-described embodiment perform determination for each clock under a stable condition, and therefore, a determination time is very short, regardless of a frequency difference. For example, assuming that f_{ref}=50 MHz and the number of determination cycles (Nⱼ)=10, determination may be made at 20 ns×10=200 ns and, as compared to a general example of processing performed in accordance with the related art, an asynchronous state may be detected at speed several hundred as fast as that in processing performed in accordance with the related art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A lock detection circuit comprising:
a phase difference detection circuit that detects a phase difference between a divided signal of an oscillation signal and a reference signal;
a differentiation circuit that calculates a second differential value and a third differential value of the phase difference; and
a synchronization detect circuit that detects the reference signal synchronizes with the oscillation signal, based on the secondary differential value and the third differential value.

2. The lock detection circuit according to claim 1, wherein
the phase difference detection circuit includes
delay lines that delays one of the reference signal and the divided signal in a plurality of stages and generate a plurality of delay signals with different delay amounts,
latch lines that latches the plurality of delay signals with the other one of the reference signal and the divided signal, and
a phase difference calculation circuit that calculates a phase difference from positions of multiple ones of the plurality of delay signal latched by the latch lines, values of which change.

3. The lock detection circuit according to claim 1, wherein
when a state in which each of the secondary differential value and the tertiary differential value is not zero is detected consecutively a predetermined times, the synchronization detect circuit determines an asynchronous state.

4. An oscillation source circuit comprising:
a reference signal source that generates a reference signal having a predetermined frequency;
a control oscillation circuit including
an oscillation circuit that generates an oscillation signal having a variable frequency,
a phase difference detection circuit that detects a phase difference between a divided signal of the oscillation signal and a reference signal, a differentiation circuit that calculates a second differential value and a third differential value of the phase difference, and
a synchronization detect circuit that detects the reference signal synchronizes with the oscillation signal, based on the secondary differential value and the third differential value.

5. A wireless device comprising:
an oscillation source that outputs an oscillation signal;
a transmission circuit that amplifies the oscillation signal and output a transmission signal via an antenna;
a reception circuit that receives a signal corresponding to the transmission signal and output a reception signal;
a mixer that mixes the oscillation signal to the reception signal; and
a baseband signal processing circuit that processes an intermediate frequency signal that is output by the mixer,
wherein
the oscillation source includes
a reference signal source that generates a reference signal having a predetermined frequency,
a control oscillation circuit including
an oscillation circuit that generates an oscillation signal having a variable frequency,
a phase difference detection circuit that detects a phase difference between a divided signal of the oscillation signal and a reference signal,
a differentiation circuit that calculates a second differential value and a third differential value of the phase difference, and
a synchronization detect circuit that detects the reference signal synchronizes with the oscillation signal, based on the secondary differential value and the third differential value.
